(19) United States
(12) Patent Application Publication
(10) Pub. No.: US 2009/0163024 A1
(43) Pub. Date: Jun. 25, 2009

(54) METHODS OF DEPOSITING A RUTHENIUM FILM

(75) Inventors: Jeon Ho Kim, Cheonan-si (KR); Hyung Sang Park, Seoul-si (KR); Seung Woo Choi, Cheonan-si (KR); Dong Rak Jung, Cheonan-si (KR); Chun Soo Lee, Daejeon-si (KR)

Correspondence Address: KNOBBE MARTENS OLSON & BEAR LLP, 2040 MAIN STREET, FOURTEENTH FLOOR, IRVINE, CA, 92614, US

(73) Assignee: ASM GENITECH KOREA LTD., Cheonan-si (KR)

(21) Appl. No.: 12/337,141

(22) Filed: Dec. 17, 2008

(30) Foreign Application Priority Data
Dec. 21, 2007 (KR) 10-2007-0135186

(51) Int. Cl. H01L 21/443

(52) U.S. Cl. 438/653; 257/E21.478

(57) ABSTRACT

A method of depositing includes: loading a substrate into a reactor; and conducting a plurality of atomic layer deposition cycles on the substrate in the reactor. At least one of the cycles includes steps of: supplying a ruthenium precursor to the reactor; supplying a purge gas to the reactor; and supplying non-plasma ammonia gas to the reactor after supplying the ruthenium precursor. The method allows formation of a ruthenium layer having an excellent step-coverage at a relatively low deposition temperature at a relatively high deposition rate. In situ isothermal deposition of barrier materials, such as TaN at 200-300° C., is also facilitated.

### CROSS-REFERENCE TO RELATED APPLICATIONS

This application claims priority to and the benefit of Korean Patent Application No. 10-2007-0135186 filed in the Korean Industrial Property Office on Dec. 21, 2007, the entire contents of which are incorporated herein by reference.

### BACKGROUND

1. Field of the Invention

The present invention relates to a method of depositing a thin film, and more particularly to a method of depositing a ruthenium layer.

2. Description of the Related Art

A ruthenium metal layer has been researched for use as an electrode material, for example, a gate electrode material for memory devices. Recently, various applications of ruthenium (e.g., as an electrode material for a DRAM and a diffusion barrier for a copper line) have drawn attention. When a ruthenium layer forms an electrode on a structure having a high aspect ratio (e.g., a DRAM capacitor), the ruthenium layer typically should have a thickness of at least about 10 nm.

In certain instances, a tantalum nitride (TaN) layer is formed as a diffusion barrier layer on a substrate. A copper layer may be formed on the tantalum nitride layer. However, adhesion between the copper layer and the tantalum nitride layer is poor, and thus, the copper layer may be peeled off from the tantalum nitride layer during a planarization process, e.g., a chemical mechanical polishing (CMP) process, after formation of the copper layer. A ruthenium layer may be formed between the copper layer and the tantalum nitride layer to serve as an adhesion layer for improving the adhesion between the copper layer and the tantalum nitride layer.

A physical deposition method can be used to form a ruthenium film. An exemplary physical deposition method is a sputtering method, but sputtering tends not to exhibit good step coverage, particularly in high aspect ratio applications like DRAM capacitors.

Chemical vapor deposition (CVD) methods of forming thin films of ruthenium (Ru) or ruthenium dioxide (RuO₂) are also known. Such CVD methods use an organometallic compound of ruthenium, such as a ruthenium cyclopentadienyl compound or bis(ethylcyclopentadienyl)ruthenium (Ru(EtCp)₂) and oxygen (O₂) gas as reactants. An exemplary method is disclosed by Park et al., “Metallorganic Chemical Vapor Deposition of Ru and RuO₂ Using Ruthenocene Precursor and Oxygen Gas,” J. Electrochem. Soc., 147[1], 203, 2000. CVD, employing simultaneous provision of multiple reactants, also suffers from less than perfect conformality.

Atomic layer deposition (ALD) methods of forming ruthenium thin films are also known. Generally, ALD involves sequential introduction of separate pulses of at least two reactants until a layer of a desired thickness is deposited through self-limiting adsorption of monolayers of materials on a substrate surface. For example, in forming a thin film including an AB material, a cycle of four sequential steps of: (1) a first reactant gas A supply; (2) an inert purge gas supply; (3) a second reactant gas B supply; and (4) an inert purge gas supply is repeated. Examples of the inert gas are argon (Ar), nitrogen (N₂), and helium (He). More complicated sequences are also known. Conventionally, ALD takes advantage of self-limiting surface reactions to deposit no more than one monolayer per cycle of the material.

For example, an ALD process can be conducted at a substrate temperature of about 200° C. to about 400° C. and a process pressure of about several hundred mTorr to several tens of Torr, using a ruthenium cyclopentadienyl compound (for example, liquid bis(ethylcyclopentadienyl)ruthenium [Ru(EtCp)₂]) and oxygen (O₂) gas as reactants. Such a process can form a ruthenium layer having a thickness of about 0.1 Å to 0.5 Å per cycle of supplying the reactants. See Aaltonen et al. “Ruthenium Thin Film Grown by Atomic Layer Deposition,” Chem. Vap. Deposition, 9[1], 45 2003.

A plasma enhanced atomic layer deposition (PEALD) method may also be used for depositing a ruthenium layer. In a PEALD method, dimethylcyclopentadieneruthenium (Ru(EtCp)₂) may be used as a source gas of ruthenium and ammonia NH₃ plasma may be used as a reactant.

The above information disclosed in this Background section is only for enhancement of understanding of the background of the invention and therefore it may contain information that does not form prior art already known in this country to a person of ordinary skill in the art.

### SUMMARY

In one embodiment, a method of making an integrated circuit includes: loading a substrate into a reactor; and conducting a plurality of deposition cycles. At least one of the cycles includes steps of: supplying a ruthenium precursor to the reactor; supplying a purge gas to the reactor after supplying the ruthenium precursor; and supplying non-plasma ammonia gas to the reactor after supplying the purge gas.

In another embodiment, a method of making an electronic device includes: loading a substrate into a reactor; and depositing a material over the substrate in the reactor at a temperature between about 200° C. and about 300° C. The material includes a diffusion barrier material. The method also includes conducting a plurality of atomic layer deposition (ALD) cycles on the substrate in the reactor. At least one of the cycles includes steps of: supplying a ruthenium precursor to the reactor; supplying a purge gas to the reactor; and supplying non-plasma ammonia gas to the reactor after supplying the ruthenium precursor.

### BRIEF DESCRIPTION OF THE DRAWINGS

FIG. 1A is a flowchart of a deposition method of a tantalum nitride layer according to one embodiment.

FIG. 1B is a flowchart of a deposition method of a ruthenium layer according to one embodiment.

FIG. 2A is a graph showing a deposition rate of a ruthenium layer deposited by a method according to one embodiment, depending on the deposition temperature.

FIG. 2B is a graph showing a sheet resistance of a ruthenium layer deposited by a method according to one embodiment, depending on the pulse duration of ammonia gas.

FIG. 3A and FIG. 3B are micrographs, taken with a scanning electron microscope (SEM), of side cross sections of a ruthenium layer and a copper layer deposited in a trench structure and over a stepped structure, respectively.

### DETAILED DESCRIPTION OF THE EMBODIMENTS

Exemplary embodiments of the invention will be described in detail with reference to the attached drawings such that the invention can be easily put into practice by those skilled in the art. The invention can be embodied in various forms, and is not limited to the embodiments described herein.

In some instances, a plasma enhanced atomic layer deposition (PEALD) method may be used for depositing a ruthenium layer on a substrate. The resulting ruthenium layer may be non-uniform across the substrate, possibly due to non-uniform distribution of plasma. Such non-uniformity may be caused by the inherent directionality of plasma. Thus, a ruthenium layer deposited by PEALD may have poor step coverage. In other instances where a non-plasma atomic layer deposition (ALD) method uses oxygen gas as a reducing agent, the oxygen gas may cause damage or oxidation of an underlying layer.

In certain instances, a ruthenium layer is used as an adhesion layer between a diffusion barrier layer and a copper layer. The diffusion barrier layer may be formed of a metal nitride, for example, tantalum nitride (TaN). In such instances, the deposition temperature of the tantalum nitride layer may be about 200° C. to about 300° C. The deposition temperature for a ruthenium layer in a PEALD method may be higher than that for the tantalum nitride layer. Accordingly, the tantalum nitride layer and the ruthenium layer may not be deposited under the same conditions or in the same chamber. Thus, the deposition throughput may be relatively low.

In one embodiment, a method of depositing a ruthenium layer includes loading a substrate into a reactor; and conducting a plurality of deposition cycles on the substrate in the reactor. At least one of the cycles includes steps of: supplying a ruthenium precursor to the reactor; supplying a purge gas to the reactor; and supplying non-plasma ammonia gas to the reactor after supplying the ruthenium precursor.

In some embodiments, the method also includes depositing a non-ruthenium material over the substrate in the reactor at a temperature between about 200° C. and about 300° C. prior to conducting the plurality of deposition cycles. The non-ruthenium material may be a diffusion barrier material. Examples of diffusion barrier materials include, but are not limited to, metal nitrides, e.g., tantalum nitride, titanium nitride, and tungsten nitride, and metal carbide nitrides, e.g., WNC and TaNC. The non-ruthenium materials can be deposited using any suitable deposition method, for example, atomic layer deposition or chemical vapor deposition. In one embodiment, the steps may use plasma enhanced atomic layer deposition (PEALD).

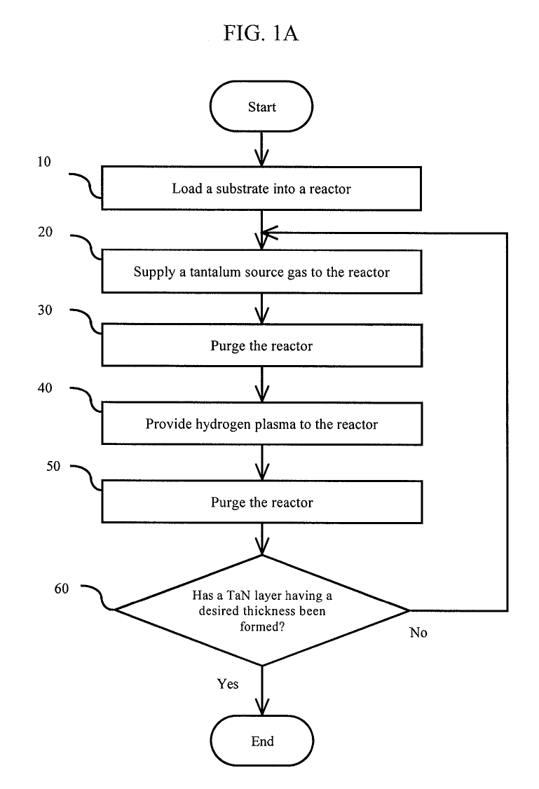

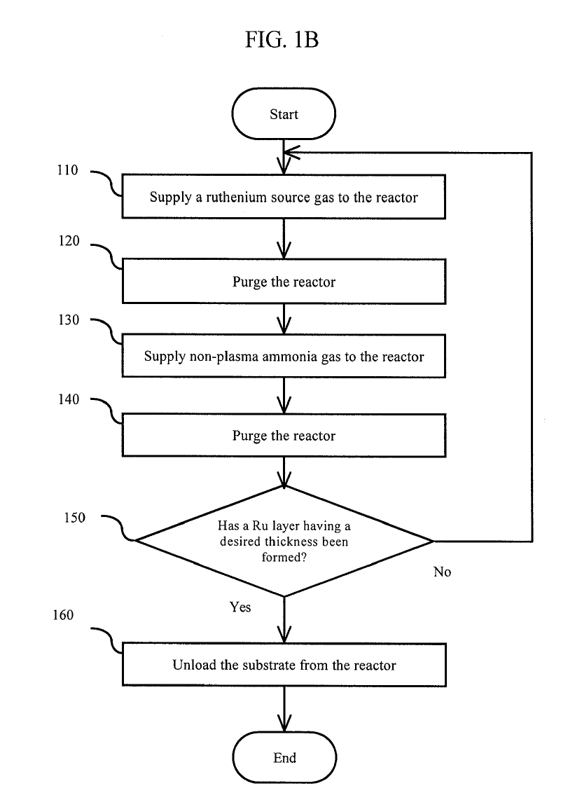

Referring to FIGS. 1A and 1B, a method of depositing layers for an electronic device according to one embodiment will be described below. The electronic device may include one or more integrated circuits. FIG. 1A is a flowchart illustrating a method of forming a tantalum nitride layer, and FIG. 1B is a flowchart illustrating a method of forming a ruthenium layer on the tantalum nitride layer in the same chamber. In some embodiments, the process of FIG. 1B can be conducted without the prior barrier deposition, or in an independent chamber.

Referring to FIG. 1A, a method of depositing a barrier layer, and particularly a tantalum nitride layer, is described below. At step 10, a substrate is loaded into a reactor. The reactor may be a single wafer ALD reactor, such as a GENI CM-2000 reactor commercially available from ASM Genitech Korea of Cheonan-si, Chungcheongnam-do, Republic of Korea.

At step 20, a tantalum source gas is supplied into the reactor. An example of tantalum source gases is TBTDET (Ta[N(C₂H₅)₂]₃[NC(CH₃)₃]; tert-butylimido tris(diethylamido) tantalum). The tantalum source gas may be supplied for a pulse duration of, for example, about 2 seconds. The tantalum source gas may be supplied with a carrier gas (such as Ar) having a flow rate of, for example, about 150 sccm.

Subsequently, at step 30, the reactor may be purged using an inert gas (such as Ar, He, or N₂) to remove any excess tantalum source gas and/or by-products from the reactor. The inert gas may be supplied for a duration of, for example, about 4 seconds at a flow rate of, for example, about 300 sccm.

At step 40, hydrogen plasma is provided to the reactor. The hydrogen plasma may be provided in-situ or remotely. In one embodiment where the hydrogen plasma is provided in-situ, hydrogen gas (H₂) may be supplied to the reactor for a duration of, for example, about 1 second at a flow rate of, for example, about 200 sccm. This flow of hydrogen gas stabilizes a hydrogen gas flow rate during subsequent plasma generation. Then, radio frequency (RF) power may be applied to the reactor to generate hydrogen plasma for a duration of, for example, about 2 seconds while continuing to supply the hydrogen gas. The RF power may range from, for example, about 300 W at a frequency of 13.56 MHz.

At step 50, the reactor may be optionally purged using an inert gas (such as Ar, He, or N₂) to remove any excess hydrogen plasma and/or by-products from the reactor. The inert gas may be supplied for a duration of, for example, about 1 second at a flow rate of, for example, about 300 sccm. The purge step 50 may be omitted in some embodiments where turning off the plasma power renders the hydrogen rapidly non-reactive with the subsequent pulses and substrate.

The above steps 20-50 can be performed at a temperature of about 200° C. to about 300° C. The steps 20-50 can be repeated until a tantalum nitride layer having a desired thickness is formed (step 60).

After completing formation of a tantalum nitride layer, a ruthenium layer can be formed on the tantalum layer in the same chamber. Referring to FIG. 1B, a ruthenium precursor is supplied to the substrate in the reactor at step 110. Examples of ruthenium precursors include, but are not limited to, bis(ethylcyclopentadienyl)ruthenium (Ru(EtCp)₂), C₆H₈Ru(CO)₃, ruthenium octanedionate (Ru(OD)₃), bis(cyclopentadienyl)ruthenium (Ru(Cp)₂), RuO₄, and ruthenium tetramethylheptadionate (Ru(thd)₃). In one embodiment, an organometallic Ru precursor, particularly C₆H₈Ru(CO)₃, may be used as a ruthenium precursor. The ruthenium precursor may be supplied at a flow rate of about 50 sccm to about 300 sccm for a pulse duration of about 0.5 seconds to about 3 seconds.

Subsequently, a purge gas may be supplied to the reactor to purge the reactor at step 120. Examples of purge gases include, but are not limited to, Ar, He, N₂, or a combination of two or more of the foregoing. The purge gas may be supplied at a flow rate of about 100 sccm to about 300 sccm for a duration of about 1 seconds to about 6 seconds.

Next, ammonia (NH₃) gas is supplied at step 130. The ammonia gas is non-plasma ammonia gas. The ammonia gas may be supplied at a flow rate of about 50 sccm to about 300 sccm for a duration of about 3 seconds to about 6 seconds.

Subsequently, a purge gas may be supplied to purge the reactor at step 140. Examples of purge gases include, but are not limited to, Ar, He, N₂, or a combination of two or more of the foregoing. The purge gas may be supplied at a flow rate of about 100 sccm to about 300 sccm for a duration of about 1 seconds to about 4 seconds. In certain embodiments, the step 140 may be omitted.

The steps 110 to 140 may form a thermal (non-plasma) ALD cycle for forming a ruthenium layer. The thermal ALD cycle may be repeated until a ruthenium layer having a desired thickness is deposited over the substrate (step 150). Under some conditions approximating ideal ALD behavior, in each of the cycles, less than one monolayer of Ru is deposited. In one embodiment, the deposition rate ranges from about 0.44 Å/cycle to about 4.85 Å/cycle. In one embodiment, the ruthenium deposition cycle may be performed at a process temperature of about 200° C. to about 300° C., or optionally about 250° C. to about 300° C.

As described above, the ruthenium deposition cycles may be performed at a process temperature of about 200° C. to about 300° C. The process temperature of the ruthenium deposition cycles is substantially the same as or overlaps with that of the prior steps for depositing the underlying barrier layers, such as a tantalum nitride layer. Accordingly, the prior steps and the ruthenium deposition cycles may be performed in the same apparatus and under substantially the same conditions, thereby enhancing the productivity of deposition.

In illustrated embodiment, the deposition of one or more non-ruthenium materials and the deposition of the ruthenium layer are performed in the same chamber of the reactor. In some embodiments, the reactor may include multiple chambers. In such embodiments, the deposition of one or more non-ruthenium materials and the deposition of the ruthenium layer may be performed in the same or different chambers in the reactor.

### Examples 1 and 2

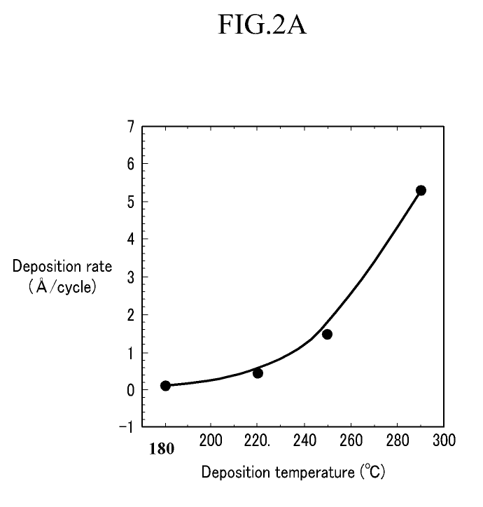

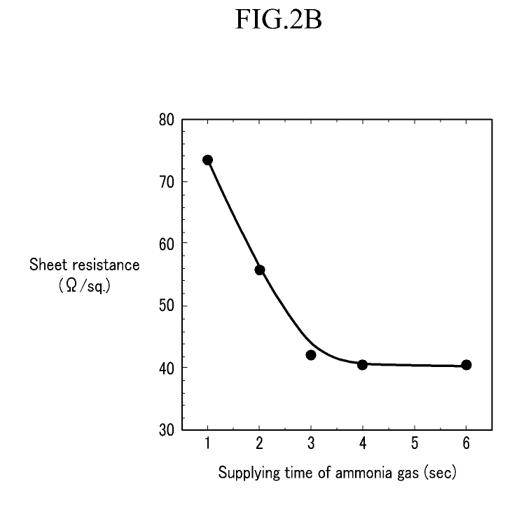

Referring to FIGS. 2A and 2B, deposition rate and properties of ruthenium layers deposited by the deposition method described above will be described below. In Example 1, ruthenium layers were deposited by the deposition method of FIG. 1B.

In Example 1, a GENI CM-2000 reactor commercially available from ASM Genitech Korea of Cheonan-si, Chungcheongnam-do, Republic of Korea was used for deposition. First, a ruthenium precursor was supplied to the reactor along with a ruthenium carrier gas, Ar gas, having a flow rate of 100 sccm for 1 second. In Example 1, C₆H₈Ru(CO)₃ was used as a ruthenium precursor. Then, the reactor was purged using Ar gas having a flow rate of 300 sccm for 4 seconds. Subsequently, ammonia gas was supplied to the reactor at a flow rate of 100 sccm for 3 seconds. The reactor was purged using Ar gas having a flow rate of 300 sccm for 4 seconds. These steps were repeated until a ruthenium layer having a desired thickness was formed. In Example 1, the ruthenium layers were deposited at different temperatures ranging from about 100° C. to about 300° C. FIG. 2A shows the deposition rates resulting from Example 1.

Referring to FIG. 2A, when the ruthenium layers were deposited at deposition temperatures in a range of about 180° C. to about 300° C., and more particularly, in a range of about 250° C. to about 300° C., the deposition rates were about 2 Å/cycle or greater. The ranges of deposition rates depending on the deposition temperature are shown in Table 1. The deposition method of the ruthenium layer according to the embodiment has a deposition rate sufficient for depositing a ruthenium layer efficiently.

TABLE 1

| Deposition temperature (° C.) | Deposition Rate (Å/cycle) |
|---|---|
| >200 | >0.4 |
| >240 | >1 |
| >260 | >2.5 |

In Example 2, ruthenium layers were deposited by the deposition method of FIG. 1B. The ruthenium layers were deposited with different pulse durations of ammonia gas at step 130. In the method, C₆H₈Ru(CO)₃ was used as a ruthenium precursor. The deposition conditions were the same as those of Example 1 except for the duration of supplying ammonia gas. The duration of supplying ammonia gas was varied from 1 second to 6 seconds. FIG. 2B shows sheet resistances of the resulting ruthenium layers.

Referring to FIG. 2B, the sheet resistance of the ruthenium layer decreases as the pulse duration of the ammonia gas is increased. This indicates that the adsorbed ruthenium precursor on the substrate and the ammonia gas more readily react with each other when the exposure to ammonia gas is increased. As shown in FIG. 2B, when the ammonia gas is supplied for 3 seconds or more, the resistance of the ruthenium layer becomes very low. Accordingly, the ruthenium layer formed by the deposition method has a relatively good sheet resistance.

### Examples 3 and 4

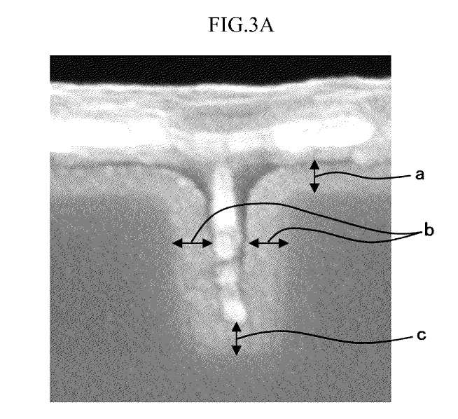

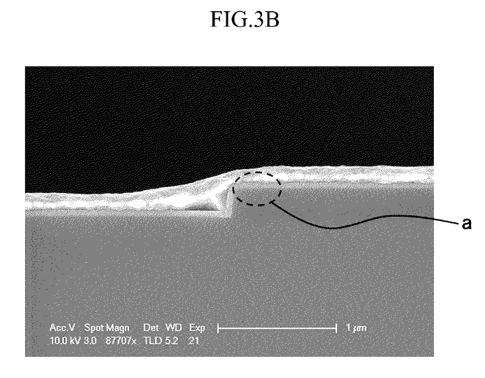

Step coverage of ruthenium layers deposited by the deposition method of FIG. 1 will be described with reference to FIG. 3A and FIG. 3B. In Example 3, a ruthenium layer was deposited on a substrate having a deep trench by the method of FIG. 1. The ruthenium layer was deposited by using C₆H₈Ru(CO)₃ as a ruthenium precursor. A copper layer was deposited by MOCVD on the ruthenium layer by using (hfac)Cu(vtms) (hfac=hexafluoroacetylacetonate; vtms=vinyltrimethylsilane) as a copper precursor. The ruthenium layer and the copper layer were deposited under process conditions shown in Table 2. In Table 2, ALD stands for atomic layer deposition, and MOCVD stands for metalorganic chemical vapor deposition.

TABLE 2

| | | Cu seed | Catalyst | Cu fill |
|---|---|---|---|---|
| Sequence | Ru deposition | deposition | treatment | deposition |
| Precursor | C₆H₈Ru(CO)₃ | (hfac)Cu(vtms) | CH₂I₂ | (hfac)Cu(vtms) |
| Temperature | 250° C. | 170° C. | 130° C. | 170° C. |
| Pressure | 3 Torr | 5 Torr | 2.2 Torr | 5 Torr |
| Process | ALD | MOCVD | Iodine flow | MOCVD |
| Thickness | 450 Å | 100 Å | <5 Å | 1,500 Å |

FIG. 3A is a micrograph, taken with a scanning electron microscope (SEM), of the resulting ruthenium layer. FIG. 3A shows a first portion (a) of the ruthenium layer deposited on a top surface of the substrate outside the trench; a second portion (b) of the ruthenium layer deposited on a sidewall of the trench; and a third portion (c) of the ruthenium layer deposited on the bottom of the trench. The first to third portions (a)-(c) have substantially the same thickness, and thus the resulting ruthenium layer has a substantially uniform and conformal thickness.

In Example 4, a ruthenium layer was deposited on a substrate having a stepped surface by the method of FIG. 1. FIG. 3B is a micrograph, taken with a scanning electron microscope (SEM), of the resulting ruthenium layer. As shown in FIG. 3B, the ruthenium layer is formed conformally on the stepped surface of the substrate. In addition, the ruthenium layer has a uniform thickness in a stepped region, as indicated by a dotted circle (a).

As described above, in the deposition method according to the embodiment, a ruthenium layer having an excellent step-coverage may be formed at a low deposition temperature with a high deposition rate. In addition, the prior steps for forming underlying layers and the ruthenium deposition steps may be performed in the same reactor under substantially the same conditions. Thus, productivity of deposition may be enhanced.

### Electronic Devices

The methods described above can be adapted for making various electronic devices. The electronic devices can include integrated circuits. Examples of electronic devices can include, but are not limited to, consumer electronic products, parts of the consumer electronic products, electronic test equipments, etc. Examples of the electronic devices can also include memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi functional peripheral device, a wrist watch, a clock, etc. Further, the electronic device can include unfinished products.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

We claim:

1. A method of making an integrated circuit, the method comprising:
loading a substrate into a reactor; and
conducting a plurality of deposition cycles, at least one of the cycles comprising steps of:
supplying a ruthenium precursor to the reactor;
supplying a purge gas to the reactor after supplying the ruthenium precursor; and
supplying non-plasma ammonia gas to the reactor after supplying the purge gas.

2. The method of claim 1, wherein all of the cycles comprising steps of:
supplying a ruthenium precursor to the reactor;
supplying a purge gas to the reactor after supplying the ruthenium precursor; and
supplying non-plasma ammonia gas to the reactor after supplying the purge gas.

3. The method of claim 1, wherein the temperature of the reactor is maintained at about 200° C. to about 300° C. during the at least one of the cycles.

4. The method of claim 3, wherein the temperature of the reactor is maintained at about 250° C. to about 300° C. during the at least one of the cycles.

5. The method of claim 1, wherein supplying the non-plasma ammonia gas comprises supplying the non-plasma ammonia for a duration of about 3 seconds to about 6 seconds.

6. The method of claim 1, wherein the ruthenium precursor is selected from the group consisting of Ru(EtCp)₂, C₆H₈Ru(CO)₃, Ru(OD)₃, RuCp₂, Ru(thd)₃, and RuO₄.

7. The method of claim 1, wherein the at least one of the cycles further comprises supplying a purge gas after the supplying the ammonia gas.

8. The method of claim 1, further comprising depositing a material over the substrate at a temperature between about 200° C. and about 300° C. prior to conducting the plurality of deposition cycles, wherein depositing the material comprises depositing the material on the substrate in the reactor after loading the substrate into the reactor.

9. The method of claim 8, wherein the plurality of deposition cycles and the deposition of the material are performed in the same chamber of the reactor.

10. The method of claim 8, wherein the reactor comprises multiple chambers, and wherein the plurality of deposition cycles and the deposition of the material are performed in different chambers in the reactor.

11. The method of claim 8, wherein the material comprises a diffusion barrier material.

12. The method of claim 11, wherein the diffusion barrier material comprises a metal nitride.

13. The method of claim 12, wherein the metal nitride is selected from the group consisting of tantalum nitride, titanium nitride, tungsten nitride, tungsten carbide nitride, tantalum carbide nitride, and combinations thereof.

14. The method of claim 11, wherein conducting the plurality of deposition cycles comprises depositing a ruthenium layer directly on the diffusion barrier.

15. The method of claim 14, further comprising depositing a conductive material directly on the ruthenium layer.

16. The method of claim 15, wherein the conductive material comprises copper.

17. The method of claim 1, wherein the substrate includes a surface that includes a trench or a step, and wherein a layer deposited by conducting a plurality of deposition cycles conforms to the trench or the step.

18. A method of making an electronic device, the method comprising:
loading a substrate into a reactor;
depositing a material over the substrate in the reactor at a temperature between about 200° C. and about 300° C., the material comprising a diffusion barrier material; and
conducting a plurality of atomic layer deposition (ALD) cycles on the substrate in the reactor, at least one of the cycles comprising steps of:
supplying a ruthenium precursor to the reactor;
supplying a purge gas to the reactor; and
supplying non-plasma ammonia gas to the reactor after supplying the ruthenium precursor.

19. The method of claim 18, wherein the material comprises a metal nitride.

20. The method of claim 19, wherein the metal nitride is selected from the group consisting of tantalum nitride, titanium nitride, tungsten nitride, tungsten carbide nitride, tantalum carbide nitride, and combinations thereof.

21. The method of claim 18, wherein the temperature of the reactor is maintained at about 200° C. to about 300° C. during the at least one of the cycles.

22. The method of claim 18, wherein supplying the non-plasma ammonia gas comprises supplying the non-plasma ammonia for a duration of about 3 seconds to about 6 seconds.

23. The method of claim 18, wherein the ruthenium precursor is selected from the group consisting of Ru(EtCp)₂, C₆H₈Ru(CO)₃, Ru(OD)₃, RuCp₂, Ru(thd)₃, and RuO₄.

24. The method of claim 18, further comprising depositing a copper layer over the substrate immediately after conducting the plurality of ALD cycles.
